(19) United States
(12) Patent Application Publication
(10) Pub. No.: US 2016/0023900 A1
(43) Pub. Date: Jan. 28, 2016

(54) OZONE GENERATOR AND OZONE GENERATION METHOD

(71) Applicant: WACOM, Chuo-ku, Tokyo (JP)

(72) Inventor: Masaki KUSUHARA, Tokyo (JP)

(21) Appl. No.: 14/442,011

(22) PCT Filed: Nov. 11, 2013
(86) PCT No.: PCT/JP2013/080469

§ 371 Date: Sep. 8, 2015

(30) Foreign Application Priority Data
Nov. 9, 2012 (JP) 2012-247804

(51) Int. Cl. C01B 13/11; C23C 16/34; C25B 1/13; C23C 16/54; C23C 16/515; C23C 16/505

(52) U.S. Cl. CPC C01B 13/115; C23C 16/515; C23C 16/505; C25B 1/13; C23C 16/54; C23C 16/345; C01B 2201/12; C01B 2201/24; C01B 2201/22

(57) ABSTRACT

In order to generate ozone, which is used for ashing and plasma cleaning, plasma generated in a decompressed chamber is conventionally used. But it is difficult to reduce the production cost of an ozone generation, because facility cost and process cost are expensive in a decompressed process. According to the present invention, ozone is generated by atmospheric pressure plasma CVD using dielectric barrier discharge generated by a plasma head where a plurality of plasma head unit members are installed in parallel to generate plasma by applying electric field or magnetic field via a dielectric member. Stable glow discharge plasma is formed even under atmospheric pressure by dielectric barrier discharge. Then, ozone can be generated under atmospheric pressure, and semiconductor device with low cost can be fabricated.

### TECHNICAL FIELD

The present invention relates an ozone generator and an ozone generation method using dielectric-barrier discharge plasma.

### BACKGROUND ART

Patent Document 1: Japanese Unexamined Patent Application Publication No. 2002-280366

In general, fabrication of semiconductor device is executed through following processes by using oxidization and CVD (Chemical Vapor Deposition) etc. These processes are a process for depositing an oxide film and a nitride film, in which oxide film and nitride film are deposited on a semiconductor substrate, for example a silicon substrate etc.; an ion implantation and heat treatment process, in which impurity region od device is formed, a process for depositing a metal film, in which a metal film that becomes wiring connecting devices is formed; a process for forming interlayer film, in which a interlayer film that insulates the wiring; a lithographic etching process, in which deposited layers are micro fabricated to desired pattern; ashing process, in which a residual organic matter like photosensitive organic resist composition etc. used at the pattern forming in the lithographic etching process is removed; and so on.

FIG. 12 shows a cross-sectional diagram indicating a structure of a conventional ashing apparatus 401, which is used in the ashing process in these processes (Patent Document 1). For example, the ashing apparatus 401 comprises a quartz chamber 402, which is nearly cylindrical chamber; packing, which covers side wall of the chamber from inner surface and edge of the side wall; a base 404, which is a bulk head and is arranged in order to cover an opening of the chamber through the packing; a bulk head 405; openable lid 410, which closes an opening arranged on the bulk head 405; an O-ring 406, which maintains air tightness between the opening and the openable lid 410; a quartz board 407, on which a semiconductor substrate executed ashing process is mounted; and an internal electrode 408 and an external electrode 409, between which discharge is executed in the ashing process period.

In the conventional ashing apparatus, inside of the quartz chamber is evacuated to make vacuum status, and the ashing process is executed. For example, oxygen is injected in the quartz chamber with vacuum degree of about 50 mTorr, discharge is executed between the internal electrode 408 and the external electrode 409, oxygen injected in the quartz chamber is decomposed to plasma by this discharge, and resist on the semiconductor substrate is removed by the generated active oxygen atom and ozone.

As described above, in the conventional ashing apparatus, film forming is executed in the reduced pressure of 10⁻²—several Torr in order to stably generate the oxygen plasma. Then, expensive facilities like decompression system etc. and decompression process in a film forming chamber are necessary, and it is difficult to reduce the fabrication cost.

### DISCLOSURE OF INVENTION

### Problem to be Solved by the Invention

The object of the present invention is to provide an ozone generator and an ozone generation method which enable the stable ozone generation in atmospheric pressure, and easily reduce a fabrication cost.

### Means for Solving the Problems

Present invention (1) is an ozone generator wherein a desired number of flow passage plates are stacked, and each discharge electrode, which is comprised of a ceramic member having a hollow portion and an electrode wire is place without contact with the ceramic member is placed at the gas outlet side of the each flow passage plate.

Present invention (2) is the ozone generator according to the invention (1), characterized in that a gas flow passage is formed along the side of the flow passage plate.

Present invention (3) is the ozone generator according to the invention (1) or (2), characterized in that the hollow portion is in a vacuum state.

Present invention (4) is the ozone generator according to the invention (1) or (2), characterized in that gas is enclosed in the hollow portion and the gas is noble gas.

Present invention (5) is the ozone generator according to the invention (4), characterized in that the pressure in the hollow portion is reduced to less than or equal to 250 Torr.

Present invention (6) is the ozone generator according to the invention (4) or (5), characterized in that the noble gas is Ar or Ne.

Present invention (7) is the ozone generator according to any one of the inventions (1) to (6), characterized in that one terminal of the electrode wire was connected to a metal foil, the end of the metal foil functions as an external extraction terminal, and the metal foil is sealed in contact with narrowed part of the ceramic member.

Present invention (8) is the ozone generator according to any one of the inventions (1) to (7), characterized in that the electrode wire is made of Ni or Ni alloy.

Present invention (9) is the ozone generator according to any one of the inventions (1) to (7), characterized in that the electrode wire is made of W including Th or ThO.

Present invention (10) is the ozone generator apparatus according to the invention (9), characterized in that the content of Th is less than or equal to 4 weight %.

Present invention (11) is the ozone generator according to any one of the inventions (1) to (10), characterized in that the electrode wire is formed with coil-like shape.

Present invention (12) is the ozone generator according to any one of the inventions (1) to (11), characterized in that a layer made of emitter material is formed on the surface of the electrode wire, and the emitter material is material with smaller work function than the material of the electrode.

Present invention (13) is the ozone generator according to the invention (12), characterized in that the emitter material is material with perovskite-type crystal structure.

Present invention (14) is the ozone generator according to the invention (12) or (13), characterized in that the emitter material is more than or equal to one chemical compound selected from the chemical compound group comprising TiSrO, MgO, TiO.

Present invention (15) is the ozone generator according to any one of the inventions (12) to (14), characterized in that the emitter layer is formed by a process wherein material of emitter layer is torn into pieces in a mortar, and resultant powder is solved in water, and the solution mixed with glue is coated on the surface of the electrode wire, and emitter layer is formed by sintering of coated wire.

Present invention (16) is the ozone generator according to any one of the inventions (12) to (14), characterized in that the emitter layer is formed by MOCVD.

Present invention (17) is the ozone generator according to any one of the inventions (7) to (16), characterized in that the metal foil is made of Mo or Mo alloy.

Present invention (18) is an ozone generator wherein a desired number of flow passage plates are stacked, and each discharge electrodes, which is comprised of a ceramic member and an electrode wire or a metal foil is enclosed inside the ceramic member, is placed at the gas outlet side of the each flow passage plate.

Present invention (19) is the ozone generator according to the invention (18), characterized in that a gas flow passage is formed along the side of the flow passage plate.

Present invention (20) is the ozone generator according to the invention (18) or (19), characterized in that the metal foil is made of Mo or Mo alloy.

Present invention (21) is the ozone generator according to any one of the inventions (1) to (20), characterized in that the ceramic member is made of quartz.

Present invention (22) is the ozone generator according to any one of the inventions (1) to (20), characterized in that the ceramic member is made of translucent alumina.

Present invention (23) is the ozone generator according to any one of the inventions (1) to (22), characterized in that the flow passage plate is made of heat resisting metal.

Present invention (24) is the ozone generator according to any one of the inventions (1) to (22), characterized in that the flow passage plate is made of ceramic.

Present invention (25) is the ozone generator according to any one of the inventions (1) to (24), characterized in that the flow passage plate is equipped with a mortise at the gas outlet side, the discharge electrode is equipped with a tenon at one side, and the discharge electrode is connected with the flow passage plate by setting in using tenon and mortise.

Present invention (26) is the ozone generator according to any one of the inventions (1) to (24), characterized in that the discharge electrode is connected with the bottom of the flow passage plate using a retainer.

Present invention (27) is the ozone generator according to any one of the inventions (1) to (24), characterized in that the flow passage plate and the discharge electrode are fabricated by integral molding.

Present invention (28) is the ozone generator according to the invention (27), characterized in that the gas flow passage the flow passage plate is processed after the integral molding of the flow passage plate and the discharge electrode.

Present invention (29) is the ozone generator according to the invention (27), characterized in that the gas flow passage is processed at the same time as the integral molding of the flow passage plate and the discharge electrode.

Present invention (30) is the ozone generator according to any one of the inventions (1) to (29), characterized in that a substrate is placed facing to the discharge electrode.

Present invention (31) is the ozone generator according to the invention (30), characterized in that the substrate can be conveyed.

Present invention (32) is the ozone generator according to the invention (31), characterized in that the substrate is a substrate with band-like shape which is conveyed by roll-to-roll process.

Present invention (33) is the ozone generator according to any one of the inventions (1) to (32), characterized in that the ozone generator is combined use type with an apparatus for the deposition of silicon nitride film and ozone treatment.

Present invention (34) is the ozone generator according to any one of the invention (1) to (32), characterized in that the ozone generator is combined use type with an apparatus for the deposition of silicon film and an ozone treatment.

Present invention (35) is the ozone generator according to the invention (33), characterized in that at least nitrogen source gas, silicon source gas and oxygen gas are supplied through the flow passage plates, and the nitrogen source gas, the silicon source gas and the oxygen gas are respectively supplied through the different flow passage plates.

Present invention (36) is the ozone generator according to the invention (33), characterized in that at least mixed gas of nitrogen source gas and silicon source gas, and oxygen gas are supplied through the flow passage plates, and the mixed gas and the oxygen gas are respectively supplied through the different flow passage plates.

Present invention (37) is the ozone generator according to any one of the inventions (1) to (36), characterized in that the ozone generator continuously executes the ozone treatment.

Present invention (38) is the ozone generator according to any one of the inventions (1) to (37), characterized in that the gas outlet is placed downward.

Present invention (39) is the ozone generator according to any one of the inventions (1) to (37), characterized in that the gas outlet is placed toward lateral direction.

Present invention (40) is the ozone generator according to any one of the inventions (31) to (39), characterized in that deposition process is carried out while positive bias voltages and negative bias voltages are alternatively applied to a plurality of neighboring discharge electrodes and negative voltage is applied to the substrate.

Present invention (41) is the ozone generator according to any one of the inventions (31) to (39), characterized in that deposition process is carried out while positive bias voltages and negative bias voltages are alternatively applied to a plurality of neighboring discharge electrodes and the substrate is set to be floating potential.

Present invention (42) is the ozone generator according to any one of the inventions (31) to (39), characterized in that deposition process is carried out while positive bias voltage is applied to a plurality of discharge electrodes and negative voltage is applied to the substrate.

Present invention (43) is the ozone generator according to the invention (40) or (41), characterized in that the ozone treatment is carried out while a dielectric substrate is placed under the substrate, and positive bias voltage is applied to the dielectric substrate.

Present invention (44) is the ozone generator according to any one of the inventions (1) to (43), characterized in that the ozone treatment is carried out while the discharge electrode is cooled down by noble gas or inert gas.

Present invention (45) is the ozone generator according to any one of the inventions (1) to (44), characterized in that electric field generated by the discharge electrode is RF electric field or pulse electric field, and plasma is generated under the RF or the pulse electric field at lower or higher frequency than 13.56 MHz.

Present invention (46) is the ozone generator according to any one of the inventions (1) to (45), characterized in that a movable quartz member is fit in a space in the gas flow passage.

Present invention (47) is an ozone generation method using the ozone generator according to any one of the inventions (1) to (46).

### Effect of the Invention

According to the present inventions (1)-(8), stable glow discharge plasma can be generated even under atmospheric pressure, and then the ozone can be generated with low cost.

According to the present inventions (9) and (10), the work function of an electrode wire can be reduced so as to enhance thermal electron emission, and then the plasma can be easily generated.

According to the present invention (11), discharge area can be enlarged due to the increase in the surface area of an electrode wire.

According to the present inventions (12)-(15), electrons are emitted not only from an electrode wire but also from emitter material so that discharge starts by lower power supply and discharge state after the start becomes more stable.

According to the present invention (16), the space in a coil can be sufficiently filled by emitter material. And emitter material can be formed more densely, and its compositional ratio can be improved.

According to the present invention (17), adhesion of the metal foil with ceramic member can be improved.

According to the present invention (18), stable glow discharge plasma can be generated even under atmospheric pressure. The ozone can be generated with low cost. Because the hollow portion is not provided, the apparatus can be easily produced.

According to the present inventions (19)-(22), stable glow discharge plasma can be generated more easily.

According to the present invention (23), thermal deformation of the flow passage plate can be prevented due to heat producing electrode.

According to the present invention (24), ceramic is excellent heat resisting material and the difference of its coefficient of thermal expansion from that of an electrode is small.

According to the present invention (25), existing flow passage plates can be utilized.

According to the present invention (26), tenon and mortise processing is not necessary and quick-release is possible.

According to the present inventions (27)-(29), it becomes easier to fabricate the apparatus.

According to the present invention (30), stable glow discharge plasma can be generated more easily.

According to the present inventions (31) and (32), speedup of ozone treatment can be achieved.

According to the present inventions (33) and (34), continuous treatment of thin film deposition and ozone treatment can be achieved.

According to the present invention (35), silicon nitride film and silicon film with high purity can be deposited using a single apparatus.

According to the present invention (36), the configuration of an apparatus can be simplified.

According to the present inventions (37) and (38), ozone treatment with excellent uniformity an be achieved.

According to the present invention (39), installation area of an apparatus can be minimized.

According to the present invention (40), stable glow discharge plasma can be generated more easily. Deposition rate can be enhanced because plasma can be generated in larger region. And the collision damage to the substrate by positive ions such as Ar ions can be weakened. The damage of deposited thin film on the substrate can be reduced so that denser thin film can be formed.

According to the present inventions (41) and (42), stable glow discharge plasma can be generated more easily.

According to the present invention (43), the collision damage to the substrate by positive ions such as Ar ions can be weakened. The damage of deposited thin film on the substrate can be reduced so that denser thin film can be formed.

According to the present invention (44), the over-heat of the discharge electrode can be prevented.

According to the present invention (45), power supply at frequency other than 13.56 MHz which is commonly used in a plasma apparatus can be utilized for a deposition process. By controlling the frequency, it is possible to minimize the damage to a thin film on the substrate.

According to the present invention (46), it is possible to control the cross-sectional area of a gas flow passage so that plasma state or film deposition state can be optimized.

### BRIEF DESCRIPTION OF THE DRAWINGS

FIG. 1 is a diagram of the structure of an electrode in the ozone generator according to the present invention.

FIGS. 2 (a) and (b) are diagrams to show process steps to fabricate the electrode in the ozone generator according to the present invention.

FIG. 3 (a) is a front view diagram of a plasma head according to the first specific example in the ozone generator of the present invention. FIGS. 3 (b) are (c) are side view diagrams of the plasma head.

FIGS. 4 (a) and (b) are respectively a front view diagram and a side view diagram of a plasma head according to the second specific example in the ozone generator of the present invention.

FIG. 5 (a) is a front view diagram of a plasma head unit member according to the first specific example in the ozone generator of the present invention. FIGS. 5 (b) and (c) are side view diagrams of the plasma head unit member.

FIG. 6 (a) is a front view diagram of a plasma head unit member according to the second specific example in the ozone generator of the present invention. FIGS. 6 (b) and (c) are side view diagrams of the plasma head unit member.

FIG. 7 (a) is a front view diagram of a plasma head unit member according to the third specific example in the ozone generator of the present invention. FIGS. 7 (b) and (c) are side view diagrams of the plasma head unit member.

FIG. 8 is a cross-sectional diagram of the ozone generator according to the embodiment of the present invention.

FIGS. 9 (a), (b) and (c) are cross-sectional diagrams of a plasma head in the ozone generator according to of the embodiment of the present invention.

FIG. 10 is a cross-sectional diagram of a plasma head in the ozone generator according to the embodiment of the present invention.

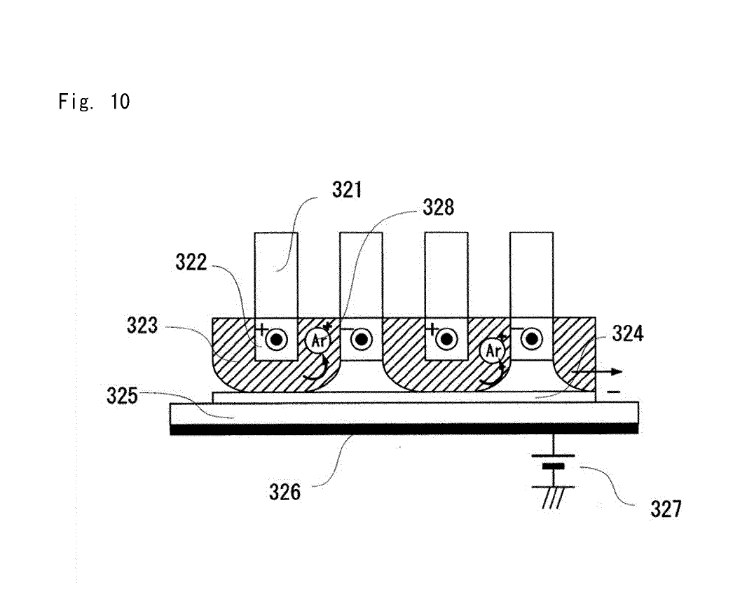

FIG. 11 is a cross-sectional diagram of a flow passage plate in the ozone generator according to the embodiment of the present invention.

FIG. 12 is a cross-sectional diagram of the conventional ozone generator.

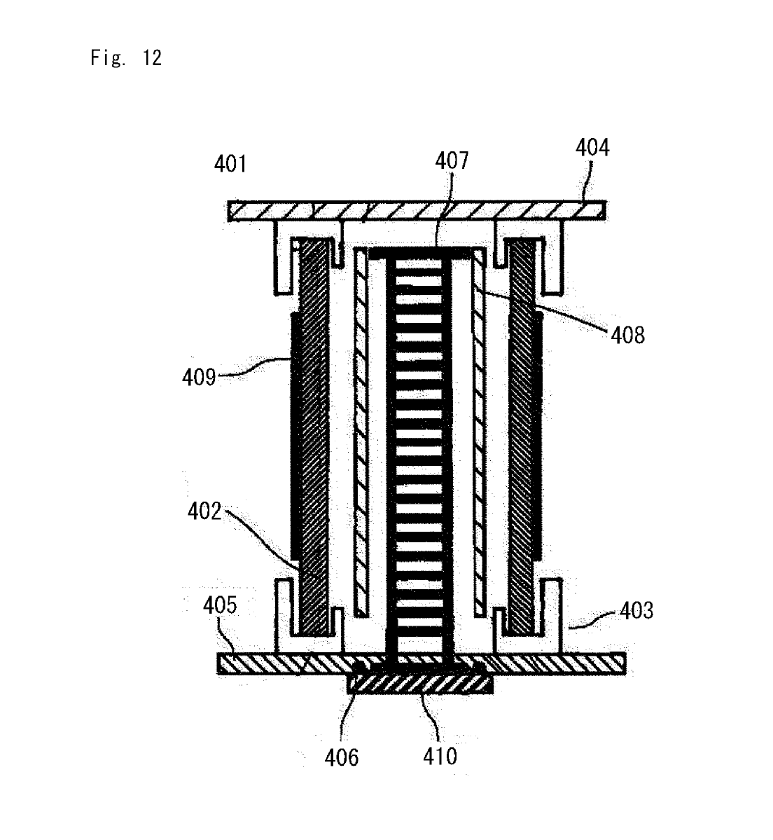

### DESCRIPTION OF THE SYMBOLS

1, 2, 3: plasma head unit member
4, 11, 15: gas introduction opening
5, 12, 16: dielectric member
6, 13, 17: plasma generation passage
7, 14, 18: plasma supply opening
8, 9: electrode
10: shock absorbing member
21, 22, 23: plasma head unit member
24, 35: gas distribution passage
25, 33: dielectric member
26, 36: plasma generation passage
27, 37: plasma supply opening
28, 29: electrode
30: shock absorbing member
31: gas distribution passage region
32: plasma generation passage region
34: gas supply pipe
41, 47, 51: gas introduction opening
42, 48, 52: dielectric member
43, 49, 53: plasma generation passage
44, 50, 54: plasma supply opening
45, 46: electrode
61, 66, 71: gas introduction opening
62, 67, 72: dielectric member
63, 68, 73: plasma generation passage
65, 70, 75: plasma supply opening
64, 69, 74: induction coil
81, 88, 95: gas introduction opening
82, 89, 96: dielectric member
83, 90, 97: plasma generation passage
85, 91, 98: plasma supply opening
84, 92, 99: induction coil
86, 87, 93, 94: coil terminal
101, 102: source gas supply unit
103: power source
104: plasma head
105, 106: plasma
107: plasma reaction region
108: thin film
109: substrate
110: substrate conveyance unit
201, 202: flow passage plate
203, 204: quartz member
205, 206: electrode wire
207, 208: gas flow direction
209: substrate
210: support member
211, 215: quartz member
212, 216: electrode wire
213, 217: electrode lead wire
214: opening
218: enclosing member
301, 306, 311, 321: flow passage plate
302, 307, 312, 322: discharge electrode
303, 308, 313, 323: plasma
304, 309, 314, 324: substrate
305, 310, 315, 325: dielectric substrate
326: electrode for applying bias voltage
327: power source for applying bias voltage
328: positive argon ion
331, 335, 339: flow passage plate
332, 336, 340: flow passage
333, 334, 337, 338, 341, 342: dielectric member
401: ashing apparatus
402: quartz chamber
403: packing
404: base
405: bulk head
406: O-ring
407: quartz board
408: internal electrode
409: external electrode
410: openable lid

### BEST MODE EMBODIMENTS FOR CARRYING OUT THE INVENTION

Best mode embodiments for carrying out the present invention are described in detail as follows.

### (Glow Discharge by Dielectric-Barrier Discharge)

Inventors of the present invention have earnestly studied realization of ozone generator under atmospheric pressure. In a conventional ozone generator, plasma cannot be stably and continuously generated, if a reaction chamber is not decompressed. Inventors of the present invention have taken notice of the structure of an electrode and the structure of a part where a substrate is placed. And they have discovered that stable plasma generation, and improvement of ozone generation efficiency become possible by the arrangement wherein an electrode is enclosed in a quartz member, and the electrode is separated from the quartz member by empty space, and a substrate is placed on a support member comprised of quartz, and plasma is supplied from a plasma head to the substrate.

And, they have employed plasma formation by dielectric-barrier discharge for stable glow discharge. Also, in order to prevent plasma reaction in a plasma generation chamber which was a problem of conventional method, a plasma head, which is a plasma generation member, is composed of a plurality of unit parts respectively having an independent plasma blow opening. The ozone generator can be used not only in the ashing process, by which resists are removed, but also for cleaning of the reaction chamber of the plasma apparatus. A plasma head is composed of a plurality of unit parts respectively having an independent plasma blow opening. For example, silicon plasma and nitrogen plasma are generated separately in each unit part in silicon nitride CVD process. And oxygen plasma for cleaning of the reaction chamber is generated by also different unit part. And also, material gases are supplied independently to each unit parts of the plasma head, and electrodes are placed so that electrical energy can be controlled independently which is applied for plasma generation. By these arrangements, thin film deposition becomes possible using best conditions for each plasma generation.

In addition, “atmospheric pressure” in this specification specifically means pressure between 8×10⁴ and 12×10⁴ Pa, while it depends on the atmospheric pressure and the altitude of the place where the apparatus is placed. When the pressure is within this range, it is possible to reduce facility cost because expensive equipment for decompression and compression is not needed.

### (Specific Example of an Electrode Structure)

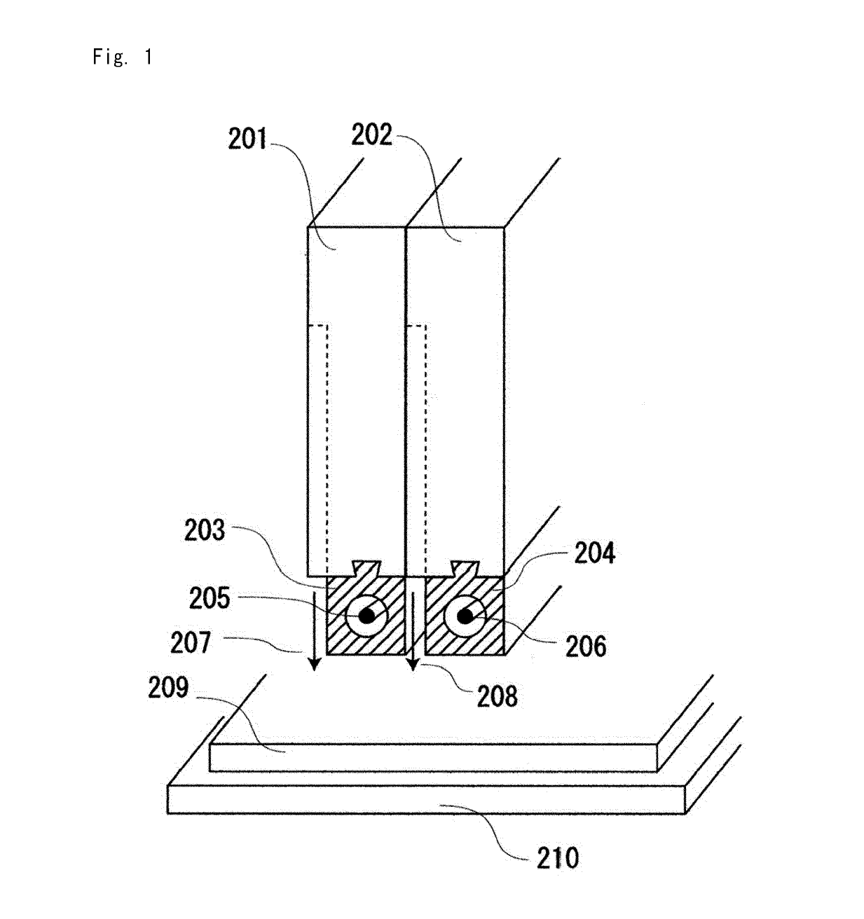

FIG. 1 is a diagram of the structure of electrode in a CVD apparatus according to the present invention. Quartz members 203, 204 are placed in the gas blowout openings of flow passage plates 201, 202 where process gas flows, and electrode wires 205, 206 are placed in the hollow portion of the quartz members 203, 204. Electrical energy due to discharge between electrode wires 205, 206 and a substrate 209 is applied to gas molecules of process gas which blows out from the gas blowout openings of flow passage plates 201, 202. Then the molecules are transformed into plasma which is supplied to the substrate 209, and silicon nitride film is deposited on the substrate 209 by the reaction of ions in the plasma. Electrode wires 205, 206 are preferably placed in the hollow portion of the quartz members 203, 204 without direct contact between them. The ambient of the hollow portion is preferably vacuum state or low-pressure state. When the ambient is low-pressure state, gas enclosed in the hollow portion is preferably noble gas such as Ar, or Ne. Preferable range of the low pressure is less than or equal to 250 Torr. Plasma is spontaneously generated by less power supply, and stable plasma generation becomes possible by uniform discharge when the hollow portion is evacuated or depressurized at the pressure less than or equal to 250 Torr with the ambient of noble gas. Flow passage plates 201, 202 are fabricated, for example, by processing aluminum plate. The substrate 209 is preferably placed on a support member 210 comprised of quartz. Then the stability of plasma is enhanced. The shape of the quartz members 203, 204 is not limited to the specific shape if they have long hollow portion so that linear electrode can be placed inside. The cross-sectional shape of the hollow portion is not limited to the specific shape, but it is preferably a circle. And the quartz members are preferably equipped with convex parts so that they can be set in the flow passage plates. The flow passage plates are equipped with concave parts corresponding to the convex parts. Alternatively, the quartz members can be equipped with concave parts and the flow passage plates can be equipped with convex parts corresponding to the concave parts.

And also, electrodes can be placed under the support member 210 for controlling bias voltage applied to the plasma. In this case, electrodes placed above the substrate 209, such as electrode wires 205, 206, are called as upper electrodes, and electrodes placed under the substrate 209 (under the support member 210) are called as lower electrodes.

As shown in FIG. 1, main body of a flow passage plate and an electrode can be fabricated as separate parts, and can be set in using tenon and mortise. Alternatively, an electrode can be placed under the flow passage plate using a retainer. A process to make mortise trench is not necessary, and it becomes easier to remove and replace these parts. And also, main body of a flow passage plate and an electrode can be fabricated by integral molding. The process to fabricate an apparatus becomes easier. A gas flow passage can be processed after the integral molding of a flow passage plate and a discharge electrode. Or it can be processed at the same time as the integral molding.

It is found that plasma is not generated when oxygen which is process gas for ozone generation is introduced from the beginning of the process, but plasma can be generated when Ar gas is introduced. Therefore, it is found that plasma which is necessary for ozone generation can be stably generated by process steps characterized in that plasma is generated by introducing Ar gas first, so that the number of electrons is increased and the flow rate of oxygen is gradually increased.

In the embodiment as shown in FIG. 1, electrode wires are not placed in direct contact with quartz members, and they are placed as floating status in a hollow portion. Alternatively, electrode wires can be placed in direct contact with quartz members without making a hollow portion, which makes fabrication of plasma head easier. The material of electrode wires or metal foil is preferably Mo or Mo alloy. Mo or Mo alloy is highly adhesive with ceramics.

The material of an insulating member of the electrode which corresponds to the above-mentioned members 203, 204 is preferably ceramics in both cases where a hollow portion is prepared or not around the electrode wire. Furthermore the material is preferably quartz or translucent alumina. And the material of the flow passage plate is preferably heat-resistant metal or ceramics.

The structure of an electrode used in the conventional ozone generator is the structure where carbon members are exposed, so there is a leakage problem of impurities included in carbon material. Meanwhile, there is no leakage problem of impurities in the structure of the electrode according to the present invention wherein an electrode wire is covered by a quartz tube.

The material of the electrode wire is preferably W. It is more preferably W which contains Th or ThO. The content of Th is preferably less than or equal to 4% by weight. This arrangement reduces the work function of the electrode wire, and facilitates the emission of thermal electrons so that plasma can be easily generated.

It is preferable that the electrode is entirely heated by appropriate external current supply to the electrode wire. When the temperature of the wire is low, nitride or silicon film can be deposited on the surface of the electrode, for example in the case of combined use type with an ozone generation and a CVD. Then it is not preferable because the flow passage may be reduced in thickness or clogged up. To the contrary, it is possible to prevent the growth of deposited material on the surface of the electrode by heating it. And also, it is possible to control the work function of metal such as Th or PTO which is added to electrode material such as W by controlling the temperature of the electrode. By these arrangements, electron density emitted from metal can be controlled so that process of ozone generation can be controlled more precisely.

And radioactive material is preferably coated on the surface of the electrode material. For example, strontium is preferably coated. Plasma can be easily excited by coating radioactive material. And also, material with smaller work function than the material of the electrode is preferably used as emitter material, and a layer of the emitter material is preferably formed on the surface of the electrode wire. Material with perovskite-type crystal structure is preferably used as the emitter material. And more than or equal to one chemical compound selected from the chemical compound group comprising TiSrO, MgO, and TiO is preferably used as the material. Any of these arrangements reduces the work function of the electrode wire, and facilitates the emission of thermal electrons so that plasma can be easily generated. The emitter layer is formed by a process wherein material of emitter layer is torn into pieces in a mortar, resultant powder is solved in water, the solution mixed with glue is coated on the surface of the electrode wire, and emitter layer is formed by sintering of coated wire. Or it can be formed by MOCVD. When the electrode wire is formed with coil-like shape, space formed in the electrode can be sufficiently filled by emitter material. And the emitter layer can be formed more densely, and its composition ratio can be improved.

And also, a quartz electrode comprised of the electrode wire in the quartz member is preferably used not only for an electrode for high frequency radiation but also used for a heater. The temperature control of a body on which deposition film is formed can be controlled, for example, by heating, by using the quartz electrode as a heater.

### (Method for Fabricating an Electrode)

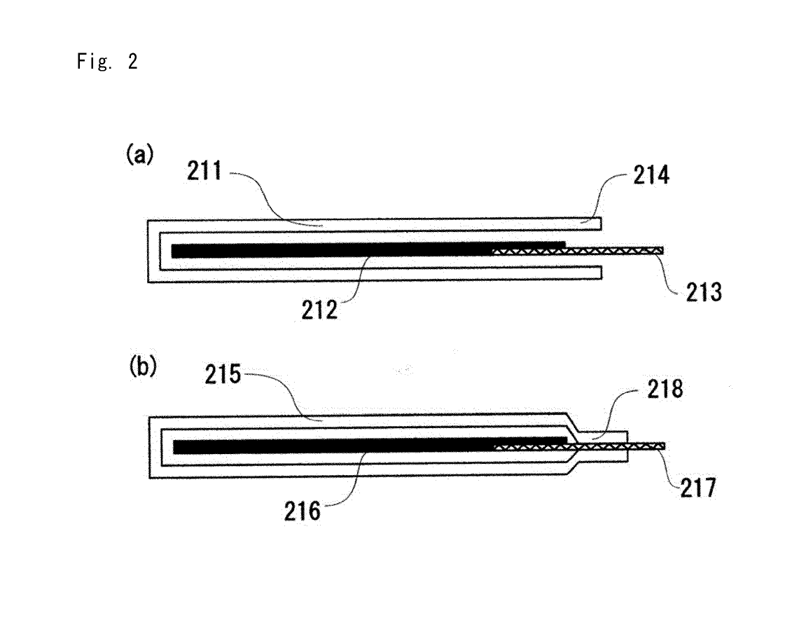

FIG. 2 (a), (b) are diagrams to show process steps to fabricate the electrode in a CVD apparatus according to the present invention. Firstly, as shown in FIG. 2(a), a quartz member 214 with a hollow portion is prepared having one terminal with an opening 214 and the other closed terminal. As an electrode 212, for example, an electrode wire made of Ni or Ni alloy is used. In FIG. 2, a linear electrode wire is shown, but an electrode wire with coil-like shape is preferably used. The surface area of the electrode can be enlarged, and the discharge area can be also enlarged by using an electrode with coil-like shape. A lead wire 213 is attached on the terminal of the electrode 212. As the lead wire, for example, metal foil with a thickness of about 20 μm made of Mo or Mo alloy is used. Next, the inside of the quartz member 211 is depressurized until the pressure reaches to vacuum, or pressure equal to or less than 250 Torr. Then the opening 214 is enclosed as shown in FIG. 2(b). According to these process steps, an electrode member is completed where an electrode 216 is supported by a lead wire 217 in a floating state without contact with a quartz member 215.

Noble gas such as Ar or Ne is preferably used for filler gas when a hollow portion is depressurized. It is more preferable that clean gas such as Ar with impurity concentration less than or equal to 10 ppb is introduced as purge gas into the hollow portion before the filler gas is introduced.

### (The First Specific Example of a Unit Part of a Plasma Head)

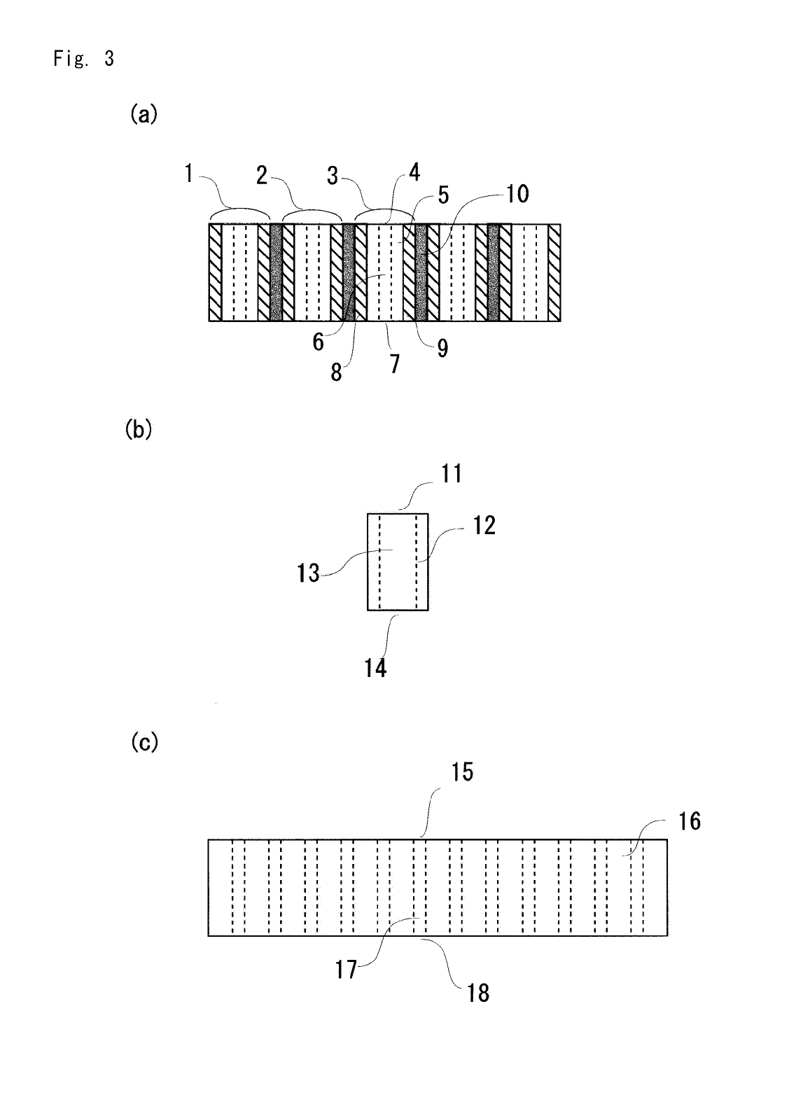

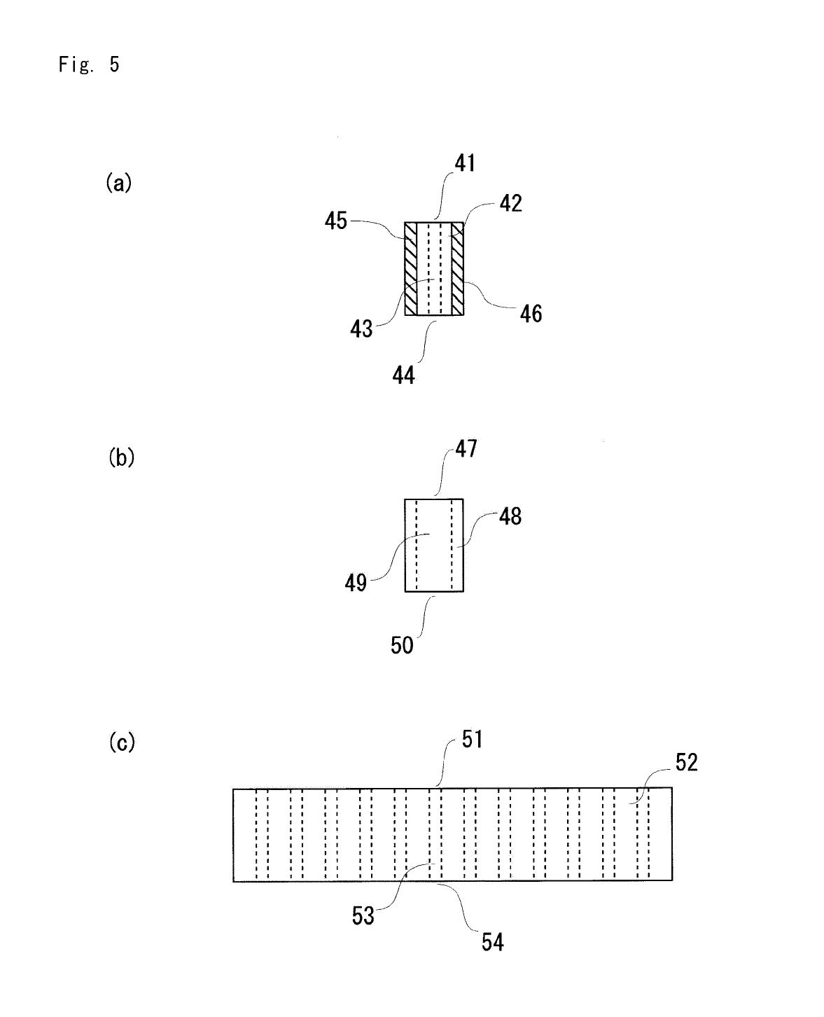

FIG. 5 (a), (b) is respectively a front view diagram and a side view diagram of a plasma head according to the first specific example of the present invention. The first specific example of the unit part is an unit part of a plasma head to generate capacitance coupling plasma. The unit part comprises a dielectric member 42 and a pair of electrodes 45, 46 which hold a dielectric member 42. The dielectric member 42 is equipped with a hole which passes through vertically, and the hole functions as a plasma generation passage 43. The dielectric member 42 can be formed as an integral member, or it can be formed by pasting or fitting a plurality of members together. When the dielectric member is composed of a plurality of members, it is preferably processed so that no leakage occurs at a joint part. One end of the hole is used as a gas introduction opening 41. Then electrical field is applied to the electrode 45, 46 which provides electrical energy to introduced gas molecules to generate plasma made of radicals, ions, and electrons. Constant, high-frequency, or pulsed electrical field can be preferably applied. Especially, pulsed electrical field can be preferably applied. Electrical field is applied via dielectric member, so even when constant electrical field is applied, accumulation and extinction of charge are repeated one after the other on the surface of dielectric member. Accordingly, plasma discharge state does not reach to be arc discharge but becomes stable glow discharge. Generated plasma blows out from a plasma supply opening 50 which is the other end of the hole. The range, where plasma is supplied, depends on the condition of plasma generation, but generally speaking, plasma is supplied in the range of several mm—several cm from the plasma supply opening 50. As shown in the side view diagram of FIG. 3(b), the unit part can be equipped with one plasma supply opening. And as shown in FIG. 5(c), it can be equipped with a plurality of plasma supply openings. When an irradiation of ozone plasma is applied on a small substrate, plasma can be supplied from one plasma supply opening. When an irradiation of ozone plasma is applied on a large substrate, plasma is preferably supplied from a plurality of plasma supply openings for better uniformity of ashing.

And also it is not necessary that a hole is prepared for a gas flow passage in dielectric member as shown in FIG. 5. A space between dielectric members can be used as a gas flow passage when the dielectric members are placed parallel to each other with a space between them.

Material of dielectric members is preferably plastic, glass, silicon dioxide, metal oxide such as aluminum oxide. Especially, quartz glass is preferably used. Dielectric member with relative permittivity greater than or equal to 2 is preferably used. Dielectric member with relative permittivity greater than or equal to 10 is more preferably used. The thickness of dielectric member is preferably in the range from 0.01 mm to 4 mm. If it is too thick, excessively high voltage is necessary for plasma generation. If it is too thin, arc discharge tends to take place.

Material of electrode is preferably metal such as copper, aluminum, stainless-steel or metal alloy.

The distance between electrodes, which depends on the thickness of dielectric member and applied voltage, is preferably in the range from 0.1 mm to 50 mm.

### (The Structure of a Plasma Head)

### (The First Specific Example of a Plasma Head)

FIG. 3 (a) is a front view diagram of a plasma head according to the first specific example of the present invention. FIG. 3 (b), (c) are side view diagrams of a plasma head according to the first specific example of the present invention. The plasma head is formed by sequentially installing one of a plurality of unit parts adjacent to the other including plasma head unit members 1, 2, 3. In FIG. 3 (a), the plasma head unit members are placed in parallel by inserting shock absorbing member 10 between the plasma head unit members. The shock absorbing member is not always an indispensable part for the plasma head structure. But it is useful for preventing the damage of dielectric member 5 by inserting the shock absorbing member when the dielectric member 5 is made of material subject to breakage such as glass and a plurality of the plasma head unit members is fixed by clenching. According to the structure of unit parts used, the plasma head can be equipped with one plasma supply opening as shown in the side view diagram in FIG. 3 (b), and it can be equipped with a plurality of plasma supply openings as shown in FIG. 3 (c).

### (The Second Specific Example of a Plasma Head)

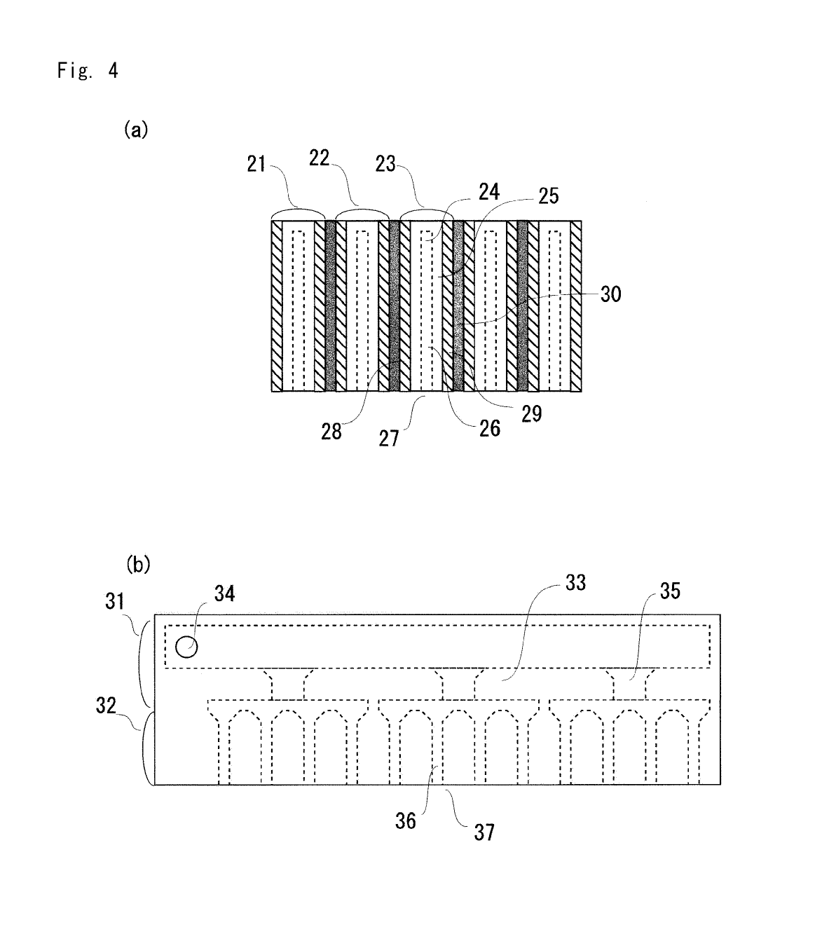

FIG. 4 (a), (b) are respectively a front view diagram and a side view diagram of a plasma head according to the second specific example of the present invention. Plasma head is formed by sequentially installing one of a plurality of unit parts adjacent to the other including plasma head unit members 21, 22, 23. As shown in the side view diagram in FIG. 2 (b), plasma head is equipped with a plurality of plasma supply openings. A dielectric member 35 is processed so that it is equipped with a hollow portion inside. This hollow portion functions as a gas distribution passage and a plasma generation passage. A hollow portion can be formed in the dielectric member as an integral part. Or a hollow portion can be formed by that a concave part is formed in one dielectric plate and the other plate is bonded to the former plate. Material gas for plasma generation is supplied from a gas supply opening 34. A gas distribution passage region is formed in the upper part of the dielectric member 35, the region which distributes gas supplied from the gas supply opening 34 into a plurality of plasma generation passages 36. According to this structure, material gas can be equally supplied to many plasma generation members using a simple structure so as to contribute downsizing of ozone generator.

### (The Structure of an Ozone Generator)

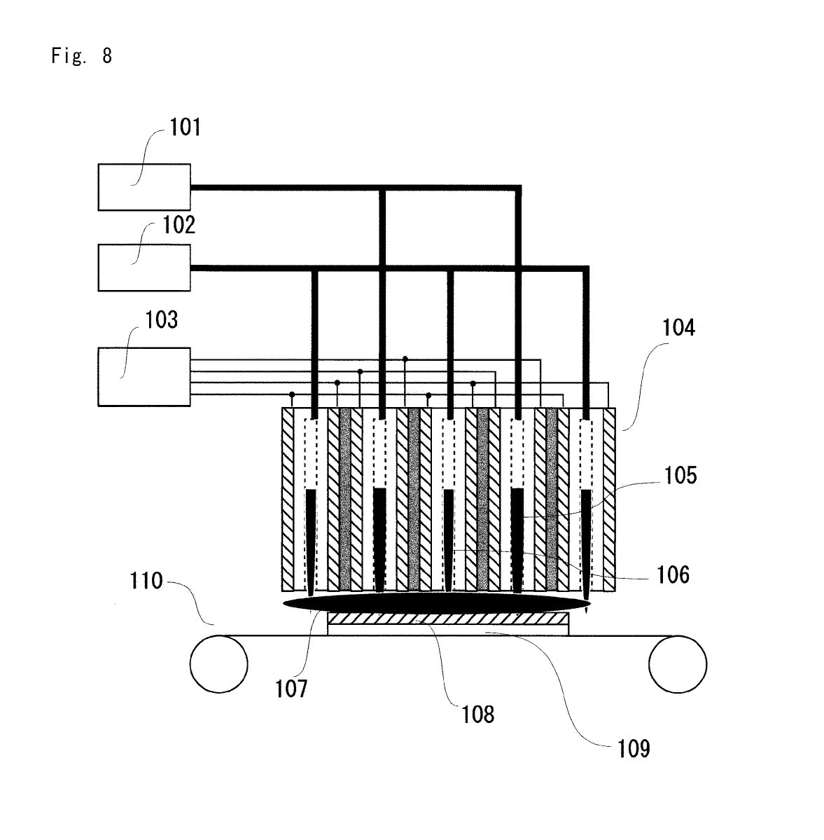

FIG. 8 is a cross-sectional diagram of an ozone generator according to the embodiment of the present invention. An ozone generator consists of a source gas supply unit 101 supplying the first gas, a source gas supply unit 102 supplying the second gas, a plasma head 104 which is formed by sequentially installing a plasma head unit member adjacent to a shock absorbing member, a power source 103 which supplies electrical power to the plasma head unit member, and a substrate conveyance unit 110 which conveys substrates. At lease one of the source gas is oxygen. A plasma head unit member consists of a dielectric member equipped with plasma generation passage and an electrode. Material gas is introduced from the upper gas introduction opening, and electric field is applied by an electrode via a dielectric member to excite the material gas for generating plasma comprising radicals, ions, and electrons in the plasma generation passage. Generated plasma is supplied from a plasma supply opening to a substrate 109 placed on the substrate conveyance unit 110. A substrate process such as ashing is carried out while substrates are conveyed by a substrate conveyance unit which enables consecutive process. The shape of the substrate is preferably band-like shape which is conveyed by roll-to-roll process. Or another process can be adopted in which a substrate is placed on a static position during deposition process, and after the deposition is finished, the substrate is conveyed so that the next substrate is in the deposition position by the substrate conveyance unit.

In addition, a lower electrode, which is not shown in the diagram, is placed under the substrate 109, and it can apply bias voltage from under the substrate.

Plasma supply openings can be placed downward as shown in FIG. 8, or they can be placed toward lateral direction. When the plasma supply openings are placed downward, the uniformity of deposition can be improved. When they are placed toward lateral direction, the installation area of the apparatus can be minimized.

Because plasma discharge is dielectric barrier discharge, plasma becomes stable glow discharge, and it becomes non-equilibrium plasma where the temperature of electrons is high and that of radicals and ions is low. By this, the excessive temperature rise of the substrate can be avoided.

Silicon nitride film can be deposited by independently supplying silicon source gas and nitrogen source gas through flow passage plates laying side-by-side among a plurality of flow passage plates. Alternatively, silicon nitride film can be deposited by supplying a mixed gas made of silicon source gas and nitrogen source gas through identical flow passage plates.

The configuration of an apparatus can be simplified. As another example of deposited film, silicon film can be deposited by not supplying nitrogen source gas but supplying silicon source gas. An ozone plasma can be produced by independently supplying oxygen gas through a flow passage plate neighbored the above plates. During this process, it is possible to flow curtain-enclosed gas made of inert gas such as nitrogen through flow passage plates surrounding the plates for source gases. The flow rates of silicon source gas, nitrogen source gas and oxygen gas can be independently controlled, which enables precise control of process conditions.

During the excitation of plasma for deposition process or ozone generation etc., it is preferable to cool down an electrode by introducing a mixed gas comprising or including noble gas (for example, Ar and N₂) nearby the electrode in the flow passage plate. When an electrode is not cooled down, and the temperature of the electrode itself rises by plasma excitation, a film which is not a dielectric member in use or extraneous material is attached on the surface of the electrode, and the function of the electrode is disabled. To prevent this problem, it is preferable to circulate cooling gas in a temperature of about 20° C.

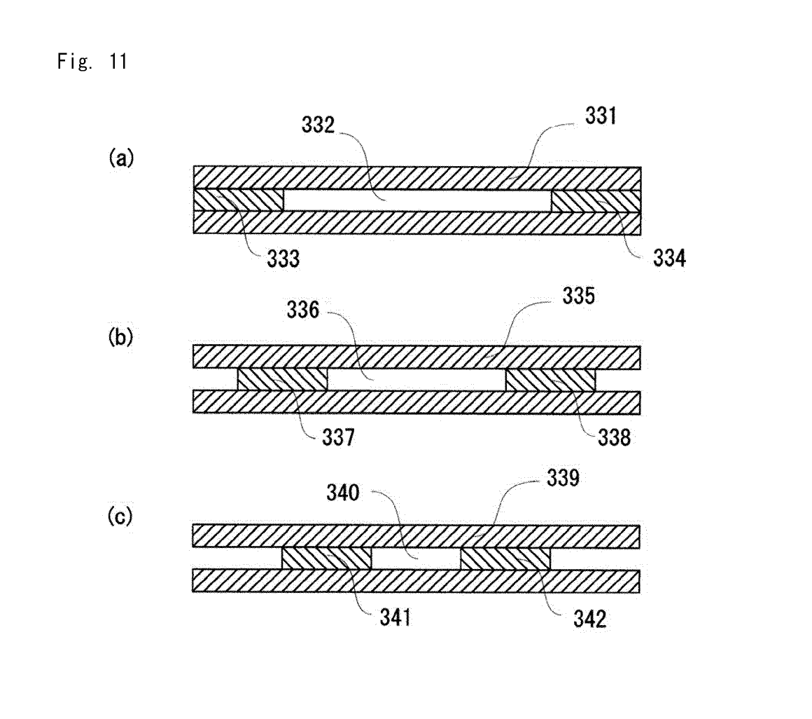

And also, a movable dielectric member is preferably fit in a space in gas flow passage or flow passage plate through which process gas or carrier gas flows. Quartz is preferably used as a dielectric member. By this arrangement, it is possible to control the cross-sectional area of flow passage so that the controllability of the process can be improved. FIGS. 11 (a), (b) and (c) are cross-sectional diagrams of a flow passage plate in an ozone generator according to the practical example of the present invention. The cross-sectional area of a flow passage 332 (FIG. 11 (a)) surrounded by a flow passage plate 331 and dielectric members 333, 334 can be controlled by moving the dielectric members 333, 334 as shown in a flow passage 336 (FIG. 11 (b)) and a flow passage 340 (FIG. 11 (c)). The flow rate of process gas can be controlled by controlling the cross-sectional area of a flow passage. For example, the flow rate can be increased by narrowing the cross-sectional area of a flow passage.

### (Plasma Generation Parameters)

Process conditions to generate plasma are appropriately determined according to the purpose to utilize plasma. When capacitance coupling plasma is generated, plasma is generated by applying constant electric field, high frequency electric field, pulsed electric field, micro-wave electric field between a pair of electrodes. When electric field is applied other than constant electric field, the used frequency can be 13.56 MHz which is used in a general plasma apparatus, or it can be higher than or lower than 13.56 MHz. In Patent Document 6, a technology to prevent plasma damage on the deposited film by using high frequency plasma of 100 MHz in a plasma apparatus is disclosed. By controlling the frequency of electric field, characteristics such as deposition rate, the quality of deposited film can be optimized.

Pulsed electric field is preferably used for plasma generation. Its field intensity is preferably in the range from 10 to 1000 kV/cm. Its frequency is preferably higher than or equal to 0.5 kHz.

### (Inductive Coupling Plasma Apparatus)

### (The Second Specific Example of a Unit Part of a Plasma Head)

Technical idea concerning plasma head according to the present invention is not limited to be applied for a plasma head for capacitance coupling plasma, but for example, it can be applied for a plasma head for inductive coupling plasma.

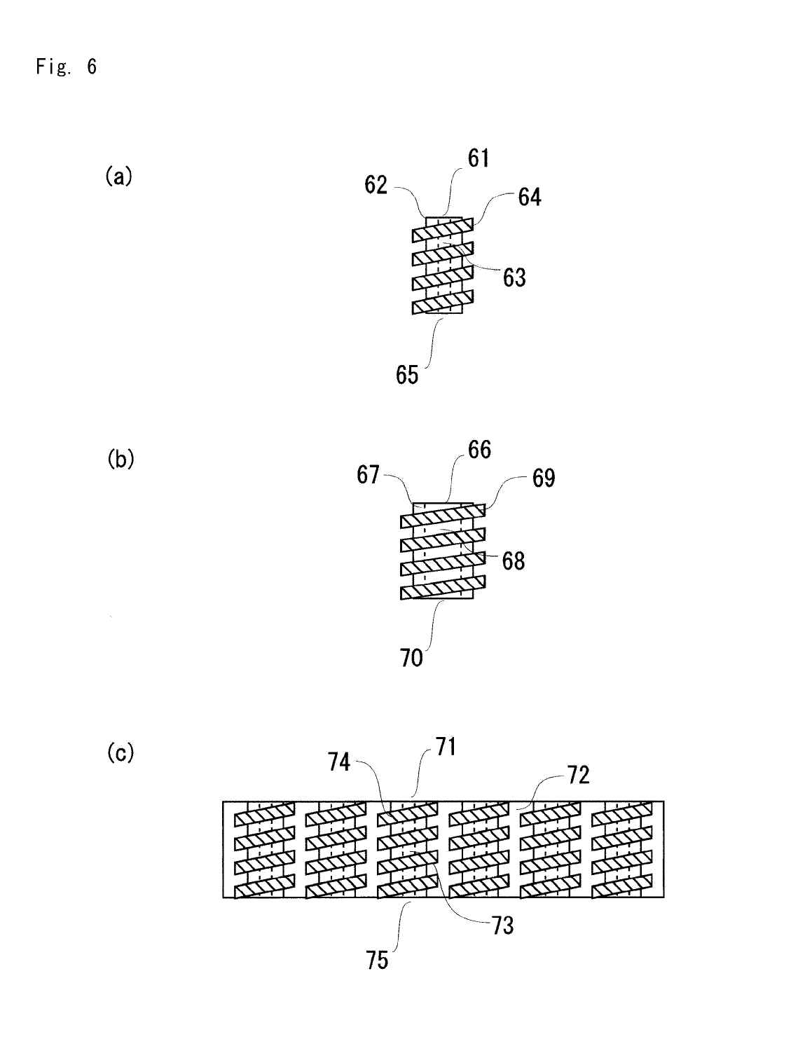

FIG. 6 (a) is a front view diagram of a plasma head unit member according to the second specific example of the present invention. FIG. 6 (b), (c) is a side view diagram of a plasma head according to the second specific example. The second specific example is the unit member of the plasma head for generating induction coupling plasma. The unit part consists of a dielectric members 62 and an induction coil 64 circumferentially placed adjacent to the member. The dielectric member 62 is equipped with a hole which passes through vertically, and the hole functions as a plasma generation passage 63. The dielectric member 62 can be formed as an integral member, or it can be formed by pasting or fitting a plurality of members together. When the dielectric member is composed of a plurality of members, it is preferably processed so that no leakage occurs at a joint part. One end of the hole is used as a gas introduction opening 61. Then electrical current is applied to the induction coil 64, and generated magnetic field provides magnetic energy to introduced gas molecules to generate plasma made of radicals, ions, and electrons. Plasma discharge state becomes stable glow discharge. Generated plasma blows out from plasma supply opening 65 which is the other end of the hole. The range, where plasma is supplied, depends on the condition of plasma generation, but generally speaking, plasma is supplied in the range of several mm-several cm from the plasma supply opening 65. As shown in the side view diagram of FIG. 6(b), the unit part can be equipped with one plasma supply opening. And as shown in FIG. 6(c), it can be equipped with a plurality of plasma supply openings. When an ozone treatment is applied on a small substrate, plasma can be supplied from one plasma supply opening. When an ozone treatment is applied on a large substrate, plasma is preferably supplied from a plurality of plasma supply openings.

### (The Third Specific Example of a Plasma Head)

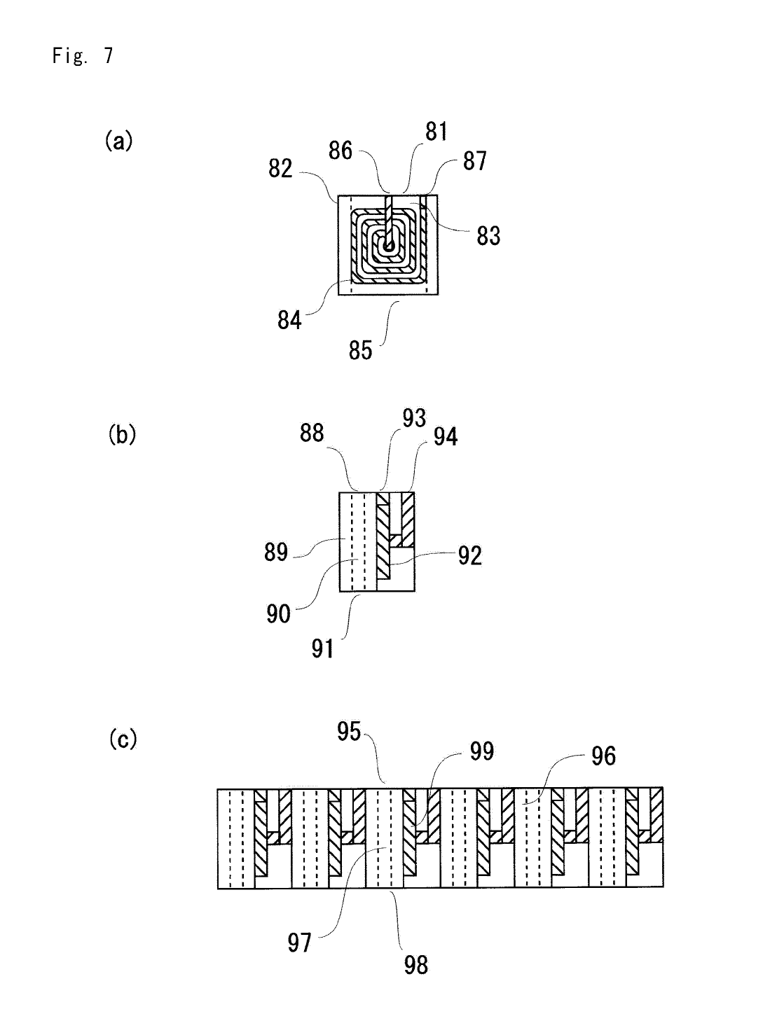

FIG. 7 (a) is a front view diagram of a plasma head unit member according to the third specific example of the present invention. FIG. 7 (b), (c) is a side view diagram of a plasma head according to the third specific example. The third specific example is the unit member of the plasma head for generating induction coupling plasma. The unit part consists of a dielectric members 82 and an induction coil 84 placed adjacent to the member. The dielectric members 82 is equipped with a hole which passes through vertically, and the hole functions as a plasma generation passage 83. The dielectric member 82 can be formed as an integral member, or it can be formed by pasting or fitting a plurality of members together. When the dielectric member is composed of a plurality of members, it is preferably processed so that no leakage occurs at a joint part. The terminals 86, 87 of the induction coil 84 are placed well away from each other through dielectric member so that they are not electrically shorted. One end of the hole is used as a gas introduction opening 81. Then electrical current is applied to the induction coil 84, and generated magnetic field provides magnetic energy to introduced gas molecules to generate plasma made of radicals, ions, and electrons. Plasma discharge state becomes stable glow discharge. Generated plasma blows out from plasma supply opening 85 which is the other end of the hole. The range, where plasma is supplied, depends on the condition of plasma generation, but generally speaking, plasma is supplied in the range of several mm-several cm from plasma supply opening 85. As shown in the side view diagram of FIG. 7(b), the unit part can be equipped with one plasma supply opening. And as shown in FIG. 7(c), it can be equipped with a plurality of plasma supply openings. When an ozone treatment is applied on a small substrate, plasma can be supplied from one plasma supply opening. When an ozone treatment is applied on a large substrate, plasma is preferably supplied from a plurality of plasma supply openings.

### (Method for Fabricating a Plasma Head)

### (Bonding Method)

To fabricate dielectric members making up a plasma head according to the present invention, it is necessary to process a hollow portion with a complicated shape such as a plasma generation passage and a gas distribution passage. Such a dielectric member with a hollow portion can be fabricated by bonding dielectric members with a hollow portion or by bonding a dielectric member with a hollow portion and a flat dielectric member after forming a hollow portion on the surface of a plurality of dielectric members.

A plasma head unit member is formed by stacking an electrode or an induction coil on the dielectric member with a hollow portion formed by this way. Furthermore, a plasma head is formed by stacking a plurality of plasma head unit parts via a shock absorbing member made of material such as Teflon™.

### (Injection Molding Method)

A plasma head unit member can be fabricated by an injection molding method. A hydraulic core and an electrode or an induction coil are placed in a mold, and material of a dielectric member is injected in the mold, then a fabricated part is unmolded and the hydraulic core is removed with the electrode or the induction coil left behind. Furthermore, a plasma head is formed by stacking a plurality of plasma head unit members via a shock absorbing member made of material such as Teflon (registered trademark).

### INDUSTRIAL APPLICABILITY

As described above, by using the ozone generator and the ozone generation method according to the present invention, fabrication cost of ozone treatment, for example, ashing or plasma cleaning, can reduced.

### Preferred Embodiments

Several embodiments according to the present invention are described in detail as follows, but the present invention is not limited to these embodiments.

### Preferred Embodiment 1

### The First Test on Electrodes

Minimum supply voltage necessary to spontaneously generate plasma was measured by setting different several conditions for the ambient of a hollow portion and gas which flows in the flow passage plate in order to investigate optimum conditions for plasma generation for an electrode (upper electrode) with a hollow portion according to the present invention. For comparison, a discharge electrode without a hollow portion was measured. And also, a flow passage plate was formed using ceramic members, and a gas flow passage was formed on the lateral side of the flow passage plate.

Minimum RF power (w) necessary for
spontaneously generating plasma

| | Gas (carrier gas) which flows | | |
|---|---|---|---|
| | in a flow passage plate | | |
| Ambient in a | | Ar 85% | |
| hollow portion | Ar 100% | N₂ 15% | Ar 70% N₂ 30% |
| Ar gas enclosed at 50 Torr | 500 (W) | 900 | 2000 |
| Ar gas enclosed at 250 Torr | 700 | 1100 | 1800 |
| Ar gas enclosed at 500 Torr | 800 | 1600 | 2000 |
| Ne gas enclosed at 50 Torr | 400 | 1000 | 2200 |
| Ne gas enclosed at 250 Torr | 600 | 1100 | 1700 |
| Ne gas enclosed at 500 Torr | 900 | 1500 | 2100 |
| Atmospheric pressure | 600 | 1500 | 1300 |
| Vacuum | 500 | 1500 | 2100 |
| Without a hollow portion | 600 | 1000 | 2100 |

In addition, members as follows were used for the components of a discharge electrode.
An electrode wire: a linear electrode wire made of Ni, one terminal was connected to a metal foil made of Mo, emitter material was not used Ceramic member: quartz

It was found to be optimum for film forming in the case that power output necessary for spontaneously generating plasma was less than or equal to 700 W because spark discharge was not generated and plasma state was stable. And it was found that Ar gas not including N2 was preferable for carrier gas flowing in a flow passage plate to maintain stable plasma. And it was found that vacuum or Ar gas enclosed at less than or equal to 250 Torr was preferable as an ambient of a hollow portion. And according to the other experiment using other gases as enclosed gas, excellent result was obtained when noble gas such as Ne was used as carrier gas and enclosed gas in the hollow portion, the result being similar to the result when Ar was used.

### Preferred Embodiment 2

### The Second Test on Electrodes

Next, minimum RF power necessary for spontaneous plasma generation was measured using an electrode formed according to the present invention by changing the material of members and the condition of gas which flows in a flow passage plate. Discharge electrodes were equipped with hollow portions filled with noble gas at a pressure of 250 Torr. The flow passage plate was made of heat resisting metal and gas flow passages were formed along the side of the plate.

Minimum RF power (W) necessary for
spontaneously generating plasma

| Ambient in a | Gas (carrier gas) which flows in a flow passage plate | | |
|---|---|---|---|
| hollow portion | Ar 100% | Ar 85% N₂ 15% | Ar 70% N₂ 30% |
| Condition 1 | 700 (W) | 1000 | 1700 |
| Condition 2 | 800 | 1100 | 1800 |
| Condition 3 | 600 | 900 | 1600 |
| Condition 4 | 800 | 1000 | 1800 |
| Condition 5 | 1000 | 1300 | 2100 |
| Condition 6 | 700 | 1000 | 1700 |
| Condition 7 | 700 | 1100 | 1600 |
| Condition 8 | 600 | 1000 | 1600 |

Condition 1: a linear electrode wire made of Ni alloy, one terminal was connected to a metal foil made of Mo, emitter material was not used, ceramic member was made of quartz, and Ni—W alloy was used as Ni alloy.
Condition 2: a linear electrode wire made of Ni, one terminal was connected to a metal foil made of Mo alloy, emitter material was not used, ceramic member was made of quartz, and Mo—W alloy was used as Mo alloy.
Condition 3: a linear electrode wire made of W including 1 weight % of Th, one terminal was connected to a metal foil made of Mo, emitter material was not used, and ceramic member was made of quartz.
Condition 4: a linear electrode wire made of W including 4 weight % of Th, one terminal was connected to a metal foil made of Mo, emitter material was not used, and ceramic member was made of quartz.
Condition 5: a linear electrode wire made of W including 10 weight % of Th, one terminal was connected to a metal foil made of Mo, emitter material was not used, and ceramic member was made of quartz.
Condition 6: a linear electrode wire made of W including 4 weight % of ThO, one terminal was connected to a metal foil made of Mo, emitter material was not used, and ceramic member was made of quartz.
Condition 7: a linear electrode wire made of Ni, one terminal was connected to a metal foil made of Mo, emitter material was not used, and ceramic member was made of translucent alumina.
Condition 8: a coiled electrode wire made of Ni, one terminal was connected to a metal foil made of Mo, emitter material was not used, and ceramic member was made of quartz.

### Preferred Embodiment 3

### The Third Test on Electrodes

Next, minimum RF power necessary for spontaneous plasma generation was measured using an electrode formed according to the present invention by changing a layer made of emitter material formed on the surface of an electrode wire and the condition of gas which flows in a flow passage plate. Discharge electrodes were equipped with hollow portions filled with noble gas at a pressure of 250 Torr.

Minimum RF power (W) necessary for
spontaneously generating plasma

| Ambient in a | Gas (carrier gas) which flows in a flow passage plate | | |
|---|---|---|---|
| hollow portion | Ar 100% | Ar 85% N₂ 15% | Ar 70% N₂ 30% |
| Condition 9 | 800 (W) | 1100 | 1800 |
| Condition 10 | 600 | 900 | 1500 |
| Condition 11 | 700 | 1000 | 1400 |
| Condition 12 | 700 | 900 | 1600 |
| Condition 13 | 600 | 900 | 1600 |
| Condition 14 | 700 | 1000 | 1500 |
| Condition 15 | 700 | 900 | 1400 |

Condition 9: a linear electrode wire made of Ni, one terminal was connected to a metal foil made of Mo, emitter material was not used, ceramic member was made of quartz, and Ni—W alloy was used as Ni alloy.
Condition 10: a linear electrode wire made of Ni, one terminal was connected to a metal foil made of Mo, emitter material was made of TiSrO having perovskite type crystal structure formed by glue coating and firing, and ceramic member was made of quartz.
Condition 11: a linear electrode wire made of Ni, one terminal was connected to a metal foil made of Mo, emitter material was made of MgO having perovskite type crystal structure formed by glue coating and firing, and ceramic member was made of quartz.
Condition 12: a linear electrode wire made of Ni, one terminal was connected to a metal foil made of Mo, emitter material was made of TiO having perovskite type crystal structure formed by glue coating and firing, and ceramic member was made of quartz.
Condition 13: a linear electrode wire made of Ni, one terminal was connected to a metal foil made of Mo, emitter material was made of TiSrO having perovskite type crystal structure formed by MOCVD, and ceramic member was made of quartz.
Condition 14: a linear electrode wire made of Ni, one terminal was connected to a metal foil made of Mo, emitter material was made of MgO having perovskite type crystal structure formed by MOCVD, and ceramic member was made of quartz. Condition 15: a linear electrode wire made of Ni, one terminal was connected to a metal foil made of Mo, emitter material was made of TiO having perovskite type crystal structure formed by MOCVD, and ceramic member was made of quartz.

### Preferred Embodiment 4

### The First Evaluation of Ozone Generation

When atmospheric pressure plasma is generated by supplying power from RF or LF power source via electrodes prepared for dielectric-barrier discharge, it is possible to soften the collision energy of electrons or charged reactive molecules which collide the surface of a substrate so as to control substrate damage and enhance desired reaction by, for example, applying bias voltage to the lower electrode in addition to simply applying appropriate effective voltage between the upper electrode and the lower electrode. By applying bias voltage so that plasma was generated not only between an electrode and a substrate but also between electrodes, ashing of photoresist film was executed.

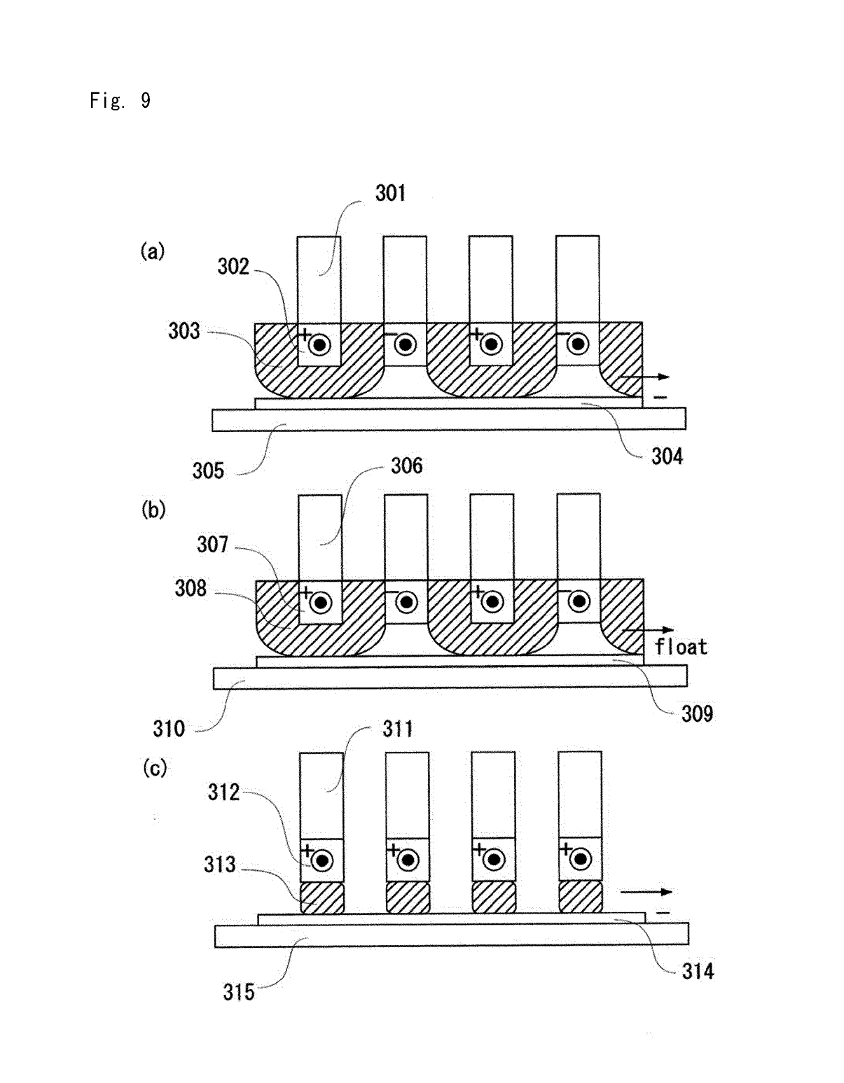

FIG. 9 (a), (b), (c) are cross-sectional diagrams of a plasma head in an ozone generator according to the embodiment of the present invention. FIG. 9 (a) is a diagram which shows a plasma generation state when a substrate was connected to ground potential and positive bias voltages and negative bias voltages were alternatively applied to a plurality of electrodes. FIG. 9 (b) is a diagram which shows a plasma generation state when a substrate was connected to floating potential in FIG. 9 (a). FIG. 9 (c) is a diagram which shows a plasma generation state when a substrate was connected to ground potential and positive bias voltages were applied to all electrodes.

Evaluation of ashing rate (relative value)

| | Present | Present | Present |
|---|---|---|---|
| | invention | invention | invention |
| | FIG. 9(a) | FIG. 9(b) | FIG. 9(c) |
| Upper electrode (+) voltage | 200 (V) | 200 | 200 |
| Upper electrode (−) voltage | 0 | 0 | NA |
| Lower electrode (−) voltage | 0 | float | 0 |
| Ashing rate | 20-40 | 15-35 | 10-30 |

In addition, members as follows were used for the components of a discharge electrode. Plasma excitation frequency was 13.56 MHz.
Electrode wires were placed in the hollow portion. The ambient of the hollow portion is vacuum state.
An electrode wire: a linear electrode wire made of Ni, one terminal was connected to a metal foil made of Mo, emitter material was not used
Ceramic member: quartz

### Preferred Embodiment 5

In order to investigate a cooling effect by a discharge electrode, an electrode temperature was measured after Ar gas plasma was generated for one hour under RF power of 2000 W applied at 13.56 MHz. The electrode temperature was 150° C. when cooling down was not done. On the other hand, when cooling down was done using Ar gas or nitrogen gas, the temperature was 50° C. and 60° C. respectively, which showed that adequate cooling effect was obtained.

1. An ozone generator wherein a desired number of flow passage plates are stacked, and each discharge electrode, which is comprised of a ceramic member having a hollow portion and an electrode wire is place without contact with the ceramic member, is placed at the gas outlet side of the each flow passage plate.

2. The ozone generator according to claim 1, characterized in that a gas flow passage is formed along the side of the flow passage plate.

3. The ozone generator according to claim 1, characterized in that the hollow portion is in a vacuum state.

4. The ozone generator according to claim 1, characterized in that gas is enclosed in the hollow portion and the gas is noble gas.

5. The ozone generator according to claim 4, characterized in that the pressure in the hollow portion is reduced to less than or equal to 250 Torr.

6. The ozone generator according to claim 4, characterized in that the noble gas is Ar or Ne.

7. The ozone generator according to claim 1, characterized in that one terminal of the electrode wire was connected to a metal foil, the end of the metal foil functions as an external extraction terminal, and the metal foil is sealed in contact with narrowed part of the ceramic member.

8. The ozone generator according to claim 1, characterized in that the electrode wire is made of Ni or Ni alloy.

9. The ozone generator according to claim 1, characterized in that the electrode wire is made of W including Th or ThO.

10. The ozone generator according to claim 9, characterized in that the content of Th is less than or equal to 4 weight %.

11. The ozone generator according to claim 1, characterized in that the electrode wire is formed with coil-like shape.

12. The ozone generator according to claim 1, characterized in that a layer made of emitter material is formed on the surface of the electrode wire, and the emitter material is material with smaller work function than the material of the electrode.

13. The ozone generator according to claim 12, characterized in that the emitter material is material with perovskite-type crystal structure.

14. The ozone generator according to claim 12, characterized in that the emitter material is one or more chemical compounds selected from the chemical compound group comprising TiSrO, MgO and TiO.

15. The ozone generator according to claim 12, characterized in that the emitter layer is formed by a process wherein material of emitter layer is torn into pieces in a mortar, and resultant powder is solved in water, and the solution mixed with glue is coated on the surface of the electrode wire, and emitter layer is formed by sintering of coated wire.

16. The ozone generator according to claim 12, characterized in that the emitter layer is formed by MOCVD.

17. The ozone generator according to claim 7, characterized in that the metal foil is made of Mo or Mo alloy.

18. An ozone generator wherein a desired number of flow passage plates are stacked, and each discharge electrode, which is comprised of a ceramic member and an electrode wire or a metal foil is enclosed inside the ceramic member, is placed at the gas outlet side of the each flow passage plate.

19. The ozone generator according to claim 18, characterized in that a gas flow passage is formed along the side of the flow passage plate.

20. The ozone generator according to claim 18, characterized in that the metal foil is made of Mo or Mo alloy.

21. The ozone generator according to claim 1, characterized in that the ceramic member is made of quartz.

22. The ozone generator according to claim 1, characterized in that the ceramic member is made of translucent alumina.

23. The ozone generator according to claim 1, characterized in that the flow passage plate is made of heat resisting metal.

24. The ozone generator according to claim 1, characterized in that the flow passage plate is made of ceramic.

25. The ozone generator according to claim 1, characterized in that the flow passage plate is equipped with a mortise at the gas outlet side, the discharge electrode is equipped with a tenon at one side, and the discharge electrode is connected with the flow passage plate by setting in using tenon and mortise.

26. The ozone generator according to claim 1, characterized in that the discharge electrode is connected with the bottom of the flow passage plate using a retainer.

27. The ozone generator according to, characterized in that the flow passage plate and the discharge electrode are fabricated by integral molding.

28. The ozone generator according to claim 27, characterized in that the gas flow passage is processed after the integral molding of the flow passage plate and the discharge electrode.

29. The ozone generator according to claim 27, characterized in that the gas flow passage is processed at the same time as the integral molding of the flow passage plate and the discharge electrode.

30. The ozone generator according to claim 1, characterized in that a substrate is placed facing to the discharge electrode.

31. The ozone generator according to claim 30, characterized in that the substrate can be conveyed.

32. The ozone generator according to claim 31, characterized in that the substrate is a substrate with band-like shape which is conveyed by roll-to-roll process.

33. The ozone generator according to claim 1, characterized in that the ozone generator is combined use type with an apparatus for the deposition of silicon nitride film and ozone treatment.

34. The ozone generator according to claim 1, characterized in that the ozone generator is combined use type with an apparatus for the deposition of silicon film and an ozone treatment.

35. The ozone generator according to claim 33, characterized in that at least nitrogen source gas, silicon source gas and oxygen gas are supplied through the flow passage plates, and the nitrogen source gas, the silicon source gas and the oxygen gas are respectively supplied through the different flow passage plates.

36. The ozone generator according to claim 33, characterized in that at least mixed gas of nitrogen source gas and silicon source gas, and oxygen gas are supplied through the flow passage plates, and the mixed gas and the oxygen gas are respectively supplied through the different flow passage plates.

37. The ozone generator according to claim 1, characterized in that the ozone generator continuously executes the ozone treatment.

38. The ozone generator according to claim 1, characterized in that the gas outlet is placed downward.

39. The ozone generator according to claim 1, characterized in that the gas outlet is placed toward lateral direction.

40. The ozone generator according to claim 31, characterized in that deposition process is carried out while positive bias voltages and negative bias voltages are alternatively applied to a plurality of neighboring discharge electrodes and negative voltage is applied to the substrate.

41. The ozone generator according to claim 31, characterized in that deposition process is carried out while positive bias voltages and negative bias voltages are alternatively applied to a plurality of neighboring discharge electrodes and the substrate is set to be floating potential.

42. The ozone generator according to claim 31, characterized in that deposition process is carried out while positive bias voltage is applied to a plurality of discharge electrodes and negative voltage is applied to the substrate.

43. The ozone generator according to claim 40, characterized in that the ozone treatment is carried out while a dielectric substrate is placed under the substrate, and positive bias voltage is applied to the dielectric substrate.

44. The ozone generator according to claim 1, characterized in that the ozone treatment is carried out while the discharge electrode is cooled down by noble gas or inert gas.

45. The ozone generator according to claim 1, characterized in that electric field generated by the discharge electrode is RF electric field or pulse electric field, and plasma is generated under the RF or the pulse electric field at lower or higher frequency than 13.56 MHz.

46. The ozone generator according to claim 1, characterized in that a movable quartz member is fit in a space in the gas flow passage.

47. An ozone generation method using the ozone generator according to claim 1.
